(19) United States
(12) Patent Application Publication
(10) Pub. No.: US 2007/0184566 A1
(43) Pub. Date: Aug. 9, 2007

(54) Neutrino receiver

(76) Inventor: Robert W. Beckwith, Clearwater, FL (US)

Correspondence Address: Leo J. Aubel, 111 Rivershire Lane, Lincolnshire, IL, 60069, US

(21) Appl. No.: 11/732,898

(22) Filed: Apr. 5, 2007

Related U.S. Application Data
(63) Continuation-in-part of application No. 11/410,356, filed on Apr. 25, 2006.
(60) Provisional application No. 60/687,494, filed on Jun. 3, 2005.

(51) Int. Cl. H01F 21/06; H01L 21/00

(52) U.S. Cl. 438/20; 310/340

(57) ABSTRACT

Velocity (energy) modulated neutrino receiver devices consist of barium titanate bodies, feedback circuits to prevent front circuits from picking up acoustic energy from neutrino modulators, and spaces to permit modulated neutrinos to pass through said bodies from front to back forming a modulated neutrino receiver device. One or more such devices may be mounted in series for greater sensitivity

Application Ser. No. 11/410,356 claims the date of Provisional Patent Application No. 60/687,494 filed Jun. 3, 2005. This application it a continuation in part of application Ser. No. 11/410,356.

A review of information on the web under the subject of Brownian energy indicates that this information is not useful in this patent application, Rather I submit a new law of nature:

The Beckwith law of nature whereby neutrinos cause all neutrons and protons of nature to vibrate thus holding energy at levels in proportion to the strength of the field of neutrinos.

A brief description of figures useful in describing the inventive devices and circuits:

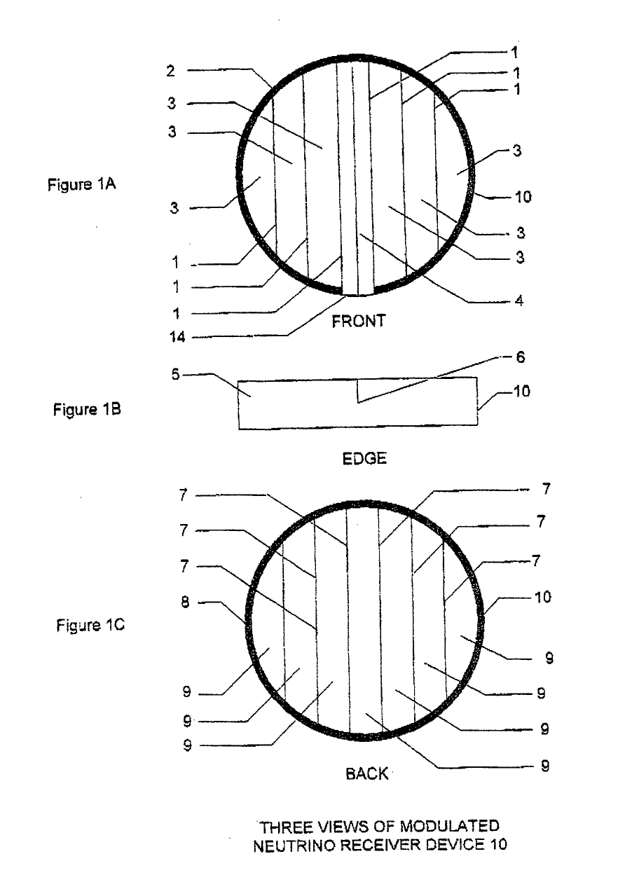

FIGS. 1a, 1b, and 1a respectively shows the front, edge and back of a modulated neutrino receiver device.

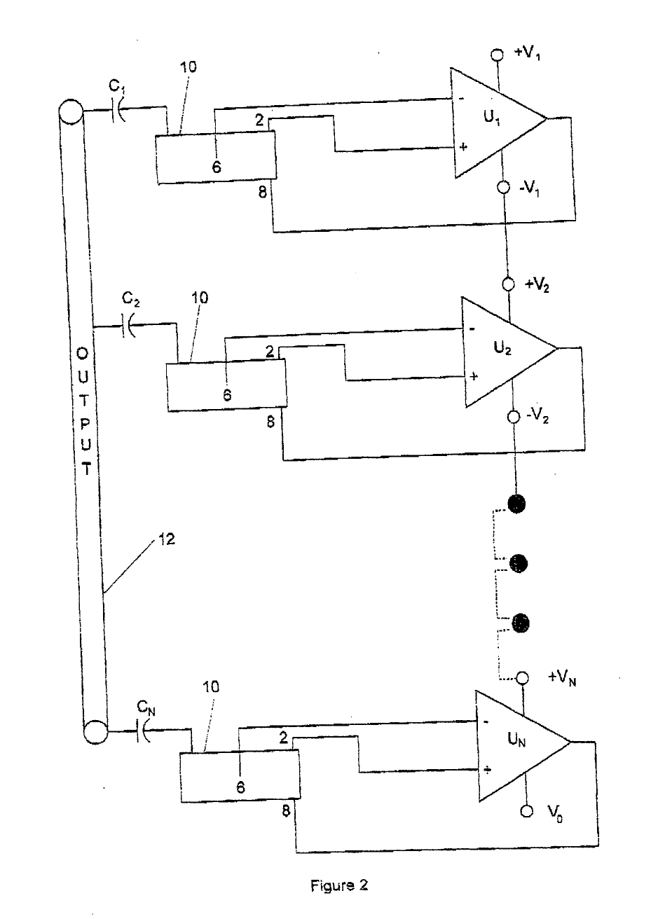

FIG. 2 shows a series assembly of N devices with their op amps U1 through Un.

### DESCRIPTION OF THE INVENTIVE DEVICES AND COMBINATION OF DEVICES

Work under patent application Ser. No. 11/410,355 has resulted in an operating neutrino modulator device. To complete a neutrino telescope a modulated neutrino receiver device is needed. The present invention describes in some detail the operation of a neutrino modulation receiver device. Inputs from potential manufacturers of such devices is needed. For example, the present device replaces copper surfaces usually used on the front and back of the device with an outside ring 2 connected with thin copper lines 1 leaving space for modulated neutrinos to pass through. Help from manufactures of barium titanate devices is needed to determine now many such lines 1 are required.

FIG. 1 shows the front of the modulated neutrino receiver disc-shaped device 10 having a plated band 2 of copper around the outside surface except for a gap 14 to allow sensor strand 4 of copper passing over the front and down the edge 5 to a point for connection 6. Sensor strand 4 exceeds across the front to a point almost touching band 2. Six parallel strands 1 of copper extend from opposing points on band 2. These form a front connection to the barium titanate device yet leaving spaces 3 for modulated neutrinos to pass into.

The back of device 10 has plated band 8 around the entire circumference. Six parallel strands 7 of copper extend from opposing points on band 8 to form a back connection to the modulated neutrino receiver device 10 yet leaving spaces 9 for modulated neutrinos to leave decline 10.

FIG. 2 shows an assembly of N devices 10 mounted with spaces in between in such a way that modulated neutrinos pass through all of the N devices 10.

Operational amplifiers (op-amps) U1 through Un are Linear Technology Model LTC6244 having essentially no voltage drop from outputs to negative power supply voltages. The op-amp power supplies are connected in series with approximately 2.8 volts do required per op-amp.

Typically op-amp Un Vo (voltage out) is connected to ring 8 on the back side of a device 10. Differences in voltages on the − (summing) input of Un and the + input of Un (which is connected via connection 6 to the sensing wire 4 of the device 10) are amplified by op-amp Un and fed back to the back side via ring 8 and cause the thickness of Un to change, bringing surface 2 to equal the position of sensing wire 4. In this way audible sounds from the vibrating modulator tube do not enter the front surface of device 10 and therefore pass no audio energy through the related device 10.

Op-amps U1 through Un are placed on a flexible printed circuit board the same width as the edge S. Cemented in place, circuits are arranged so as to be soldered to front and back circuits where the edge meets the front and back. In this way the load on the op-amps is made very low and voltage drops across the loads very small. The minimum rated voltage for operation of the op-amps is 2.8 volts and the drop across each series op-amp therefore may be only slightly more than 2.8 volts

Protons and neutrons all have a Beckwith movement energy caused by neutrinos hitting them in random fashion. Protons and neutrons in the barium titanate of devices 10 absorb more energy from neutrinos when they are traveling faster than when they are traveling slower as modulated by said prior art velocity modulator. The barium titanate discs with surfaces front and back then put out voltages representing the neutrino energy modulation. These tire varying voltages are fed through capacitors C1 through Cn to common output connection 12. This output is capable of being amplified by amplifiers not shown.

One method of mounting more than one device 10 in series is to use a molded rubber tray with holes into which device 10s may be inserted.

1. A method of making a modulated neutrino wave receiver, the method comprising the steps of:
a) placing a barium titanate disc in the path of received neutrinos for receiving neutrinos from a modulating tube,
b) using feedback circuits for preventing receiving signals from said neutrino modulating tube,
c) providing spaces for permitting modulated neutrinos to pass through said disc,
d) using said disc for generating signals resulting from chances in Beckwith energy representing modulation of said neutrinos, and
e) using capacitors for coupling said signals to an output, for further processing of the signals.

2. A method as in claim 1 further comprising in combination the steps of:
a) allowing neutrinos to pass through more than one modulated neutrino receiver for increasing the sensitivity of neutrino modulation signals, and
b) using capacitors for coupling neutrino signals to a common point,
